(19) United States
(12) Patent Application Publication
(10) Pub. No.: US 2021/0351325 A1
(43) Pub. Date: Nov. 11, 2021

(54) LED DISPLAY, METHOD FOR REPAIRING THE SAME, AND LED CHIP

(71) Applicant: CHONGQING KONKA PHOTOELECTRIC TECHNOLOGY RESEARCH INSTITUTE CO., LTD., Chongqing (CN)

(72) Inventors: Jen-Chieh CHANG, Chongqing (CN); Ruilin XU, Chongqing (CN); Kai-Yi WU, Chongqing (CN); Jan-Hsiang YANG, Chongqing (CN)

(21) Appl. No.: 17/382,971

(22) Filed: Jul. 22, 2021

Related U.S. Application Data
(63) Continuation of application No. PCT/CN2020/114617, filed on Sep. 10, 2020.

(30) Foreign Application Priority Data
Mar. 18, 2020 (CN) 202010192516.6

(51) Int. Cl. H01L 33/38; H01L 33/62; H01L 27/15; G09G 3/00

(52) U.S. Cl. CPC H01L 33/382; G09G 3/006; H01L 27/156; H01L 33/62

(57) ABSTRACT

An LED display, a method for repairing the same, and an LED chip are provided. The LED display includes a planarization layer and a circuit layer. The planarization layer is provided with a first spare electrode and a second spare electrode on an upper surface of the planarization layer. The first spare electrode is coupled with a thin film transistor in the circuit layer and the second spare electrode is coupled with a power line grounding terminal in the circuit layer. The planarization layer defines a groove inside which a diode chip is installed. The groove is provided with a first contact electrode and a second contact electrode at a bottom thereof. Each of two electrodes of the diode chip is coupled with a respective one of the first contact electrode and the second contact electrode.

### CROSS-REFERENCE TO RELATED APPLICATION(S)

This application is a continuation of International Application No. PCT/CN2020/114617, filed on Sep. 10, 2020, which claims priority to Chinese Patent Application No. 202010192516.6, filed on Mar. 18, 2020, the disclosures of which are hereby incorporated by reference in their entireties.

### TECHNICAL FIELD

This disclosure relates to the field of light-emitting diode (LED) technologies, and in particular to an LED display, a method for repairing the same, and an LED chip.

### BACKGROUND

Micro LED, that is, the miniaturization and matrixing technology of light-emitting diodes, has good stability, long lifetime, and advantages in operating temperature. The micro LED also inherits advantages of LED such as low power consumption, high color saturation, fast response speed, strong contrast, and the like, which has great application prospects.

### SUMMARY

According to implementations of the disclosure, an LED display is provided. The LED display includes a display backplane. The display backplane includes a substrate, a circuit layer, and a planarization layer stacked in order. The planarization layer is provided with a first spare electrode and a second spare electrode along a first direction on a surface of the planarization layer which is away from the circuit layer. The first spare electrode is coupled with a thin film transistor in the circuit layer through a through hole in the planarization layer and the second spare electrode is coupled with a power line grounding terminal in the circuit layer through a through hole in the planarization layer. The first spare electrode and the second spare electrode are each reserved to be welded with a respective one of two electrodes of a second LED chip. The planarization layer defines a groove between the first spare electrode and the second spare electrode. The groove is provided with a first contact electrode and a second contact electrode at a bottom thereof along a second direction perpendicular to the first direction. A first LED chip is installed in the groove. The first LED chip has two electrodes each welded with a respective one of the first contact electrode and the second contact electrode. The first LED chip is a flip-chip LED. The first contact electrode is coupled with the first spare electrode through a wire arranged in the bottom and a sidewall of the groove and the second contact electrode is coupled with the second spare electrode through a wire arranged in the bottom and the sidewall of the groove. A top of the diode chip does not extend beyond an opening of the groove.

According to the implementations of the disclosure, a method for repairing the LED display described above is provided. The method includes the following. In response to detecting that the first LED chip in the display backplane is damaged, the first LED chip is determined as an LED chip to-be-replaced, and a wire in the groove where the LED chip to-be-changed is received is heated with laser so as to fuse the wire. The second LED chip is placed above the groove and each of two electrodes of the second LED chip is connected with a respective one of the first spare electrode and the second spare electrode in the display backplane. Each of the two electrodes of the second LED chip is boned with the respective one of the first spare electrode and the second spare electrode.

According to the implementations of the disclosure, an LED chip is provided. The LED chip includes a first electrode and a second electrode separated from each other. A spacing between the first electrode and the second electrode is greater than a width of the LED chip

### BRIEF DESCRIPTION OF THE DRAWINGS

For ease of illustration, the disclosure is described in detail according to the following implementations and accompanying drawings.

FIG. 1 is a top view of a structure of an LED display according to the disclosure.

FIG. 2 is a section view of a structure of an LED display along X direction according to the disclosure.

FIG. 3 is an exploded view of a structure of an LED display along X direction according to the disclosure.

FIG. 4 is a section view of a structure of an LED display along Y direction according to the disclosure.

FIG. 5 is an exploded view of a structure of an LED display along Y direction according to the disclosure.

FIG. 6 is an overall structure diagram of a diode chip according to the disclosure.

FIG. 7 is a flow chart of a method for repairing an LED display according to the disclosure.

FIG. 8 is a schematic diagram illustrating a working principle of step S101 in the method for repairing an LED display according to the disclosure.

FIG. 9 is a schematic diagram illustrating a working principle of step S102 in the method for repairing an LED display according to the disclosure.

### DETAILED DESCRIPTION

To make the purposes, technical solutions, and advantages of the present application clearer, the present disclosure will be described in detail with reference to the accompanying drawings and implementations. It should be understood that the specific implementations described herein are only used to illustrate but not to limit the present disclosure.

In the description of the present disclosure, it should be understood that terms “center”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, and other indicated orientations or positional relationships are based on orientations or positional relationships shown in the drawings, and are only for the convenience of describing the present application and simplicity, but not to indicate or imply that an indicated apparatus or element must have a specific orientation, be constructed and operated in a specific orientation, and thus cannot be understood as a limit to the present disclosure. In addition, terms “first” and “second” are only used for description, and cannot be understood as indicating or implying relative importance or implicitly indicating the number of indicated technical features. Therefore, a feature defined with “first” and “second” may explicitly or implicitly include one or more of the features. In the description of the present disclosure, “multiple” means two or more than two, unless otherwise specifically defined.

In the description of the present disclosure, it should be noted that, unless otherwise clearly specified and limited, terms “installation”, “connecting”, and “connection” should be understood in a broad sense. For example, it can be a fixed connection, a detachable connection, or an integral connection. It can be a mechanical connection or an electrical connection. It can be directly connected or indirectly connected through an intermediate medium. It can be an internal communication between two elements or an interaction relationship between two elements. For those of ordinary skill in the art, specific meanings of the above-mentioned terms in the present disclosure can be understood according to specific circumstances.

The display screen made of micro light-emitting diodes is a future mainstream development direction of display equipment. In the existing process, after diode chips are transferred to a display backplane, each diode chip on the display backplane needs to be inspected. When a damaged diode chip or a diode chip in poor contact is found, the diode chip needs to be replaced. In the existing repair and replacement process, the damaged diode chip needs to be removed from the display backplane, and then a good diode chip is re-bonded at a corresponding position. Such a cumbersome process is unfavorable for fast production of products.

To overcome the forgoing defects, the disclosure aims to provide an LED display which facilitates quickly replacement of a diode chip and a method for repairing the LED display.

According to implementations of the disclosure, an LED display is provided. The LED display includes a display backplane. The display backplane includes a substrate, a circuit layer, and a planarization layer stacked in order. The planarization layer is provided with a first spare electrode and a second spare electrode along a first direction on a surface of the planarization layer which is away from the circuit layer. The first spare electrode is coupled with a thin film transistor in the circuit layer through a through hole in the planarization layer and the second spare electrode is coupled with a power line grounding terminal in the circuit layer through a through hole in the planarization layer. The first spare electrode and the second spare electrode are each reserved to be welded with a respective one of two electrodes of a second LED chip. The planarization layer defines a groove between the first spare electrode and the second spare electrode. The groove is provided with a first contact electrode and a second contact electrode at a bottom thereof along a second direction perpendicular to the first direction. A first LED chip is installed in the groove. The first LED chip has two electrodes each welded with a respective one of the first contact electrode and the second contact electrode. The first LED chip is a flip-chip LED. The first contact electrode is coupled with the first spare electrode through a wire arranged in the bottom and a sidewall of the groove and the second contact electrode is coupled with the second spare electrode through a wire arranged in the bottom and the sidewall of the groove. A top of the diode chip does not extend beyond an opening of the groove.

In an implementation, a width of the groove in the first direction is less than a spacing between the two electrodes of the first LED chip.

In an implementation, the spacing between the two electrodes of the first LED chip is greater than a width of the first LED chip.

In an implementation, the first LED chip and the second LED chip have a same size, shape, and type.

In an implementation, the planarization layer is provided with a contact point for the thin film transistor and a contact point for the power line grounding terminal at the bottom of the planarization layer. The contact point for the thin film transistor is coupled with the first spare electrode through a conducting material. The contact point for the power line grounding terminal is coupled with the second spare electrode through a conducting material. The contact point for the thin film transistor is connected with the thin film transistor in the circuit layer, and the contact point for the power line grounding terminal is connected with the power line grounding terminal in the circuit layer.

According to the implementations of the disclosure, a method for repairing the LED display described above is provided. The method includes the following. In response to detecting that the first LED chip in the display backplane is damaged, the first LED chip is determined as an LED chip to-be-replaced, and a wire in the groove where the LED chip to-be-changed is received is heated with laser so as to fuse the wire. The second LED chip is placed above the groove and each of two electrodes of the second LED chip is connected with a respective one of the first spare electrode and the second spare electrode in the display backplane. Each of the two electrodes of the second LED chip is boned with the respective one of the first spare electrode and the second spare electrode.

In an implementation, the first LED chip and the second LED chip have a same size, shape, and type.

According to the LED display of the disclosure, since the diode chip is disposed in the groove in the planarization layer and the planarization layer is provided with spare electrodes on a surface thereof, when detecting that the diode chip needs to be replaced during the production process, the diode chip can be replaced by cutting off the wire between the spare electrodes and the contact electrodes with laser and bonding a new diode chip on the spare electrodes. In this way, the new diode chip can be bonded on the contact electrodes without removing the diode chip from the backplane, which significantly improves production efficiency and facilitates fast production.

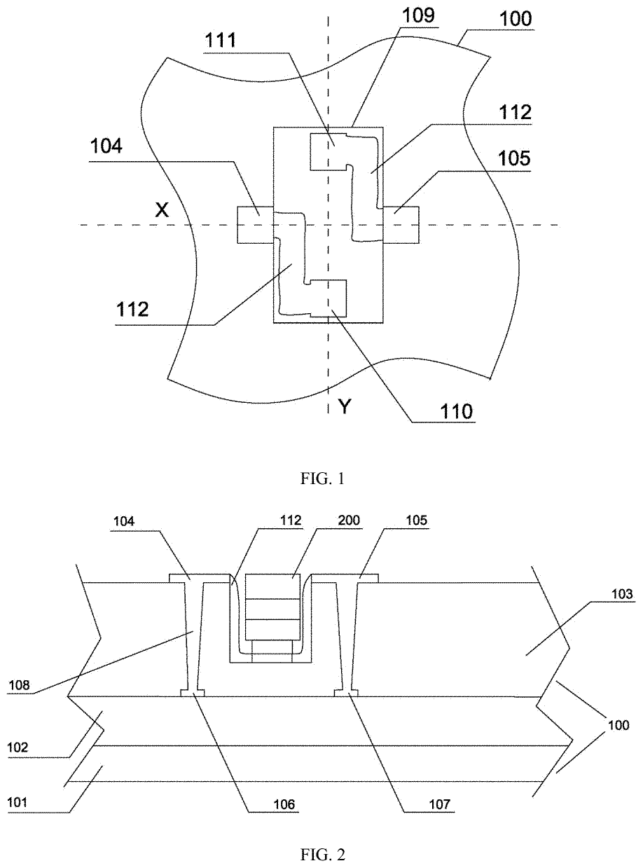

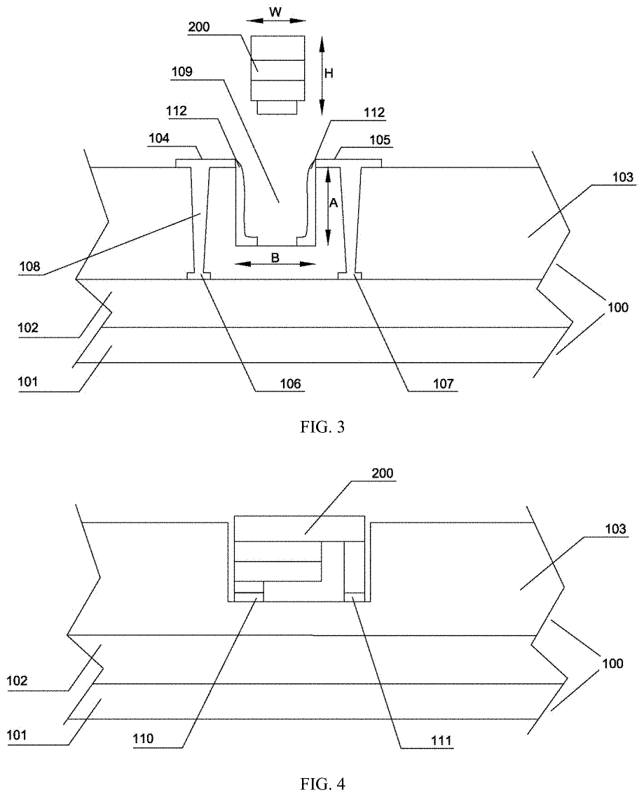

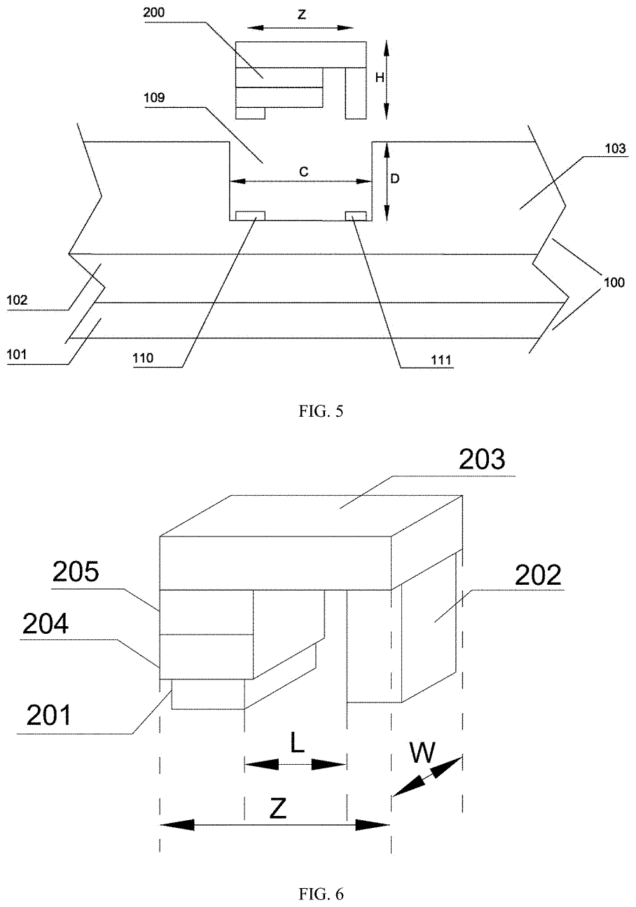

In the following, an LED display according to an implementation of the disclosure is described in detail with reference to FIG. 1 to FIG. 6. The LED display includes a display backplane 100. The display backplane 100 includes a substrate 101, a circuit layer 102, and a planarization layer 103 which are disposed from bottom to top with the substrate 101 at the bottom. The substrate 101 may include a transparent glass material, such as silica (SiO2). The substrate 101 may also include a transparent plastic material, such as organic materials like polyethersulfone (PES), polyacrylate (PAR), polyetherimide (PEI), polyethylene terephthalate (PEN), polyethylene terephthalate (PET), poly Phenyl sulfide (PPS), polyarylate, polyimide, polycarbonate (PC), cellulose triacetate (TAC), cellulose propionate (CAP), or the like. The circuit layer 102 includes a drive circuit for driving an LED chip, such as thin film transistor (TFT), gate line, signal line, etc. The planarization layer 103 covers the circuit layer 102, which can eliminate the step difference on the circuit layer 102 and make the circuit layer 102 planar. The planarization layer 103 may include organic materials such as polymethyl methacrylate (PMMA) or polystyrene (PS), polymer derivatives with phenolic groups, acrylic-based polymers, imide-based polymers, aryl ether-based polymers, amide-based polymers, Fluorine-based polymer, p-xylyl polymer, vinyl alcohol-based polymer, or any combination thereof.

The planarization layer 103 is provided with a first spare electrode 104 and a second spare electrode 105 along a first direction on a surface of the planarization layer 103 which is away from the circuit layer 102. The first spare electrode 104 and the second spare electrode 105 are each reserved to be welded with a respective one of two electrodes of a second LED chip 200a. The first spare electrode 104 is coupled with a thin film transistor in the circuit layer 102 through a through hole in the planarization layer and the second spare electrode 105 is coupled with a power line grounding terminal in the circuit layer 102 through a through hole in the planarization layer. The planarization layer 103 defines a groove 109. The first spare electrode 104 and the second spare electrode 105 are each disposed along a respective long side of an opening of the groove 209. A width of the opening of the groove 109 along the first direction is less than a spacing between two electrodes of a first LED chip 200. A first contact electrode 110 and a second contact electrode 111 are each disposed near a respective short side of the bottom of the groove 109. The LED chip 200 is installed in the groove 109. The first LED chip is a flip-chip LED. The groove 109 is provided with the first contact electrode 110 and the second contact electrode 111 at a bottom thereof along a second direction perpendicular to the first direction. The first LED chip 220 has two electrodes at a bottom thereof and each electrode is welded with a respective one of the first contact electrode 110 and the second contact electrode 111. The first contact electrode 110 and the second contact electrode 111 are coupled with the first spare electrode 104 and the second spare electrode 105 respectively through a wire 112 arranged in the bottom and a sidewall of the groove. The wire 112 may include a first wire and a second wire. The first contact electrode 110 is coupled with the first spare electrode 104 through the first wire and the second contact electrode 111 is coupled with the second spare electrode 105 through the second wire. All the wires 112 are coated on the sidewall of the groove 109. A width B of the groove 109 is greater than a width W of the first LED chip 200. A length C of the groove 109 is greater than a length Z of the first LED chip 200. Therefore, the groove 109 has an area larger than that of the first LED chip 200, which can prevent a short circuit caused by contact between the wire 112 on the sidewall of the groove 109 and other positions of the first LED chip 200. A height H of the first LED chip 200 is no greater than a height A of the groove 109, which prevents connection between the first spare electrode 104 and the second spare electrode 105 and the second LED chip 200a from being blocked by the first LED chip 200 installed in the groove 109 extending beyond the opening of the groove 109.

The planarization layer 103 is provided with a contact point 106 for the thin film transistor and a contact point 107 for the power line grounding terminal at the bottom of the planarization layer 103. A through hole 108 is formed between the first spare electrode 104 and the contact point 106 for the thin film transistor, and a through hole 108 is formed between the second spare electrode 105 and the contact point 107 for the power line grounding terminal. The through hole 108 is filled with a conducting material. The contact point 106 for the thin film transistor is coupled with the first spare electrode 104 via the conducting material and the contact point 107 for the power line grounding terminal is coupled with the second spare electrode 105 via the conducting material. The contact point 106 for the thin film transistor is connected with the thin film transistor in the circuit layer, and the contact point 107 for the power line grounding terminal is connected with the power line grounding terminal in the circuit layer. The conducting material, the contact point 106 for the thin film transistor, and the contact point 107 for the power line grounding terminal may be made of materials such as aluminum (Al), platinum (Pt), palladium (Pd), silver (Ag), magnesium (Mg), gold (Au)), nickel (Ni), neodymium (Nd), iridium (Ir), chromium (Cr), lithium (Li), calcium (Ca), molybdenum (Mo), titanium (Ti), tungsten (W), copper (Cu), etc.

The first LED chip 200 includes a first electrode 201 and a second electrode 202 separated from each other. An upper end of the second electrode 202 is coupled with a second semiconductor layer 203. An upper end of the first electrode 201 is coupled with the second semiconductor layer 203 through a first semiconductor layer 204 and a light emitting layer 205 in sequence. A spacing L between the two electrodes of the first LED chip 200 is greater than a width W of the first LED chip 200. The first LED chip 200 in the groove 109 and the second LED chip 200a may have a same size, shape, and type, which is more convenient for repair.

In the implementation, in a case of a normal state of the first LED chip 200 in the groove 109, the first spare electrode 104 and the second spare electrode 105 on either side of the groove 109 are not bonded with any diode chip. The first spare electrode 104 conducts a received electric signal to the first contact electrode 110 through the wire 112, and the second spare electrode 105 conducts a received electric signal to the second contact electrode 111 through the wire 112. The first contact electrode 110 and the second contact electrode 111 transmit the electric signals to the first LED chip 200 in the groove 109. At this point, the first spare electrode 104 and the second spare electrode 105 are each in an idle state. In a case of failure of the first LED chip 200 installed in the groove 109, the first LED chip 200 should be replaced. The wire 112 connecting the first contact electrode 110 and the wire 112 connecting the second contact electrode 111 may be cut off, so that the first LED chip 200 in the groove 109 is unable to receive electric signals. A new diode chip may be bonded with the first spare electrode 104 and the second spare electrode 105 directly. In this way, there is no need to remove the first LED chip 200 from the groove 109, which efficiently shortens the process.

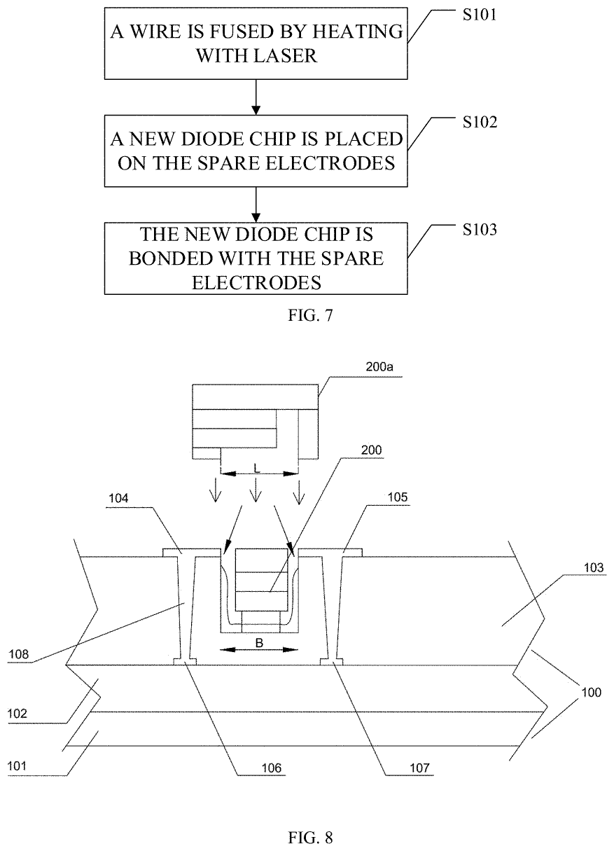

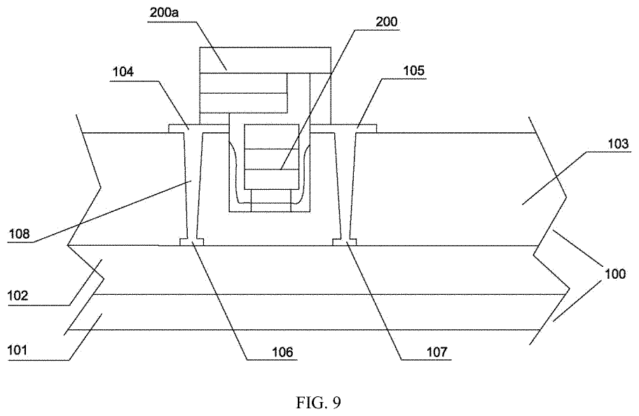

In the following, a method for repairing the LED display according to an implementation of the disclosure is described in detail with reference to FIG. 7 to FIG. 9. The method includes the following. At S101, a wire is fused by heating with laser. When detecting that the first LED chip 200 in the display backplane 100 is damaged, the first LED chip 200 is determined as the first LED chip 200 to-be-replaced. The wire 112 in the groove where the first LED chip to-be-replaced is received is heated with laser, so as to fuse the wire 112. Therefore, the first spare electrode 104 is disconnected with the first wire and the second spare electrode 105 is disconnected with the second wire. In this way, an electric connection between the first LED chip 200 to-be-replaced and the circuit layer is disconnected.

At S102, a new diode chip is placed on the spare electrodes.

The second LED chip 200a is placed above the groove. Two electrodes of the second LED chip 200a are each coupled with a respective one of the first spare electrode 104 and the second spare electrode 105. The second LED chip 200a and the first LED chip 200 to-be-replaced may have a same size, shape, and type. Since both the spacings L between two electrodes of the first LED chip 200 and between two electrodes of the second LED chip 200a are greater than the width B of the groove, the second LED chip 200a may be placed across the first spare electrode 104 and the second spare electrode 105. A long side of the second LED chip 200a is perpendicular to a long side of the first LED chip 200.

At S103, the new diode chip is bonded with the spare electrodes.

Each of the two electrodes of the second LED chip 200a is bonded with a respective one of the first spare electrode 104 and the second spare electrode 105, so as to form a repaired display backplane. In the repaired display backplane, the new diode chip is coupled with the circuit layer 102 through the first spare electrode 104 and the second spare electrode 105.

In descriptions of this specification, descriptions with reference to terms “one implementation”, “some implementations”, “exemplary implementations”, “examples”, “specific examples”, or “some examples”, etc. mean that specific features, structures, materials, or characteristics described in combination with implementations or examples are included in at least one implementation or example of the present application. In this specification, a schematic representation of above-mentioned terms does not necessarily refer to the same implementation or example. Moreover, specific features, structures, materials, or characteristics described can be combined in an appropriate manner in any one or more implementations or examples.

The above descriptions are only some implementations of the present application, and are not intended to limit the present application. Any modifications, equivalent replacements, and improvements made within the spirit and principle of the present application should fall into the scope of the present application.

What is claimed is:

1. A light-emitting diode (LED) display, comprising a display backplane, the display backplane comprising a substrate, a circuit layer, and a planarization layer stacked in order, wherein
the planarization layer is provided with a first spare electrode and a second spare electrode along a first direction on a surface of the planarization layer which is away from the circuit layer, the first spare electrode being coupled with a thin film transistor in the circuit layer through a through hole in the planarization layer and the second spare electrode being coupled with a power line grounding terminal in the circuit layer through a through hole in the planarization layer, the first spare electrode and the second spare electrode being each reserved to be welded with a respective one of two electrodes of a second LED chip;
the planarization layer defines a groove between the first spare electrode and the second spare electrode, the groove being provided with a first contact electrode and a second contact electrode at a bottom thereof along a second direction perpendicular to the first direction;
a first LED chip is installed in the groove, the first LED chip having two electrodes each welded with a respective one of the first contact electrode and the second contact electrode, the first LED chip being a flip-chip LED; and
the first contact electrode is coupled with the first spare electrode through a wire arranged in the bottom and a sidewall of the groove and the second contact electrode is coupled with the second spare electrode through a wire arranged in the bottom and the sidewall of the groove, and a top of the first diode chip does not extend beyond an opening of the groove.

2. The LED display of claim 1, wherein a width of the groove in the first direction is less than a spacing between the two electrodes of the first LED chip.

3. The LED display of claim 2, wherein the spacing between the two electrodes of the first LED chip is greater than a width of the first LED chip.

4. The LED display of claim 3, wherein the first LED chip and the second LED chip have a same size, shape, and type.

5. The LED display of claim 4, wherein the planarization layer is provided with a contact point for the thin film transistor and a contact point for the power line grounding terminal at the bottom of the planarization layer, the contact point for the thin film transistor is coupled with the first spare electrode through a conducting material, the contact point for the power line grounding terminal is coupled with the second spare electrode through a conducting material, the contact point for the thin film transistor is connected with the thin film transistor in the circuit layer, and the contact point for the power line grounding terminal is connected with the power line grounding terminal in the circuit layer.

6. A method for repairing the LED display of claim 1, comprising:
determining the first LED chip as an LED chip to-be-replaced, and heating, with laser, the wire in the groove where the LED chip to-be-changed is received so as to fuse the wire, in response to detecting that the first LED chip in the display backplane is damaged;
placing the second LED chip above the groove and connecting each of the two electrodes of the second LED chip with a respective one of the first spare electrode and the second spare electrode in the display backplane;
bonding each of the two electrodes of the second LED chip with the respective one of the first spare electrode and the second spare electrode.

7. The method of claim 6, wherein the first LED chip and the second LED chip have a same size, shape, and type.

8. An LED chip, comprising a first electrode and a second electrode separated from each other, wherein a spacing between the first electrode and the second electrode is greater than a width of the LED chip.

9. The LED chip of claim 8, wherein the LED chip is a flip-chip LED.

10. The LED chip of claim 8, further comprising a first semiconductor layer, a light emitting layer, and a second semiconductor layer, wherein an upper end of the second electrode is coupled with the second semiconductor layer, and an upper end of the first electrode is coupled with the second semiconductor layer through the first semiconductor layer and the light emitting layer in sequence.
